(19) United States
(12) Patent Application Publication
(10) Pub. No.: US 2005/0133901 A1
(43) Pub. Date: Jun. 23, 2005

(54) System and method for delivering power to a semiconductor device

(75) Inventors: Darvin R. Edwards, Garland, TX (US); Michael A. Lamson, Anna, TX (US); Gregory E. Howard, Dallas, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 10/740,123

(22) Filed: Dec. 17, 2003

(51) Int. Cl. H01L 23/58

(52) U.S. Cl. 257/691

(57) ABSTRACT

A system for delivering power to a semiconductor device includes a package substrate comprising a substrate top surface and a substrate bottom surface. The system includes a connector formed on the substrate top surface and a cable coupled to the connector. The cable is operable to deliver power and ground to a top of the package substrate.

### TECHNICAL FIELD OF THE INVENTION

The present invention relates generally to semiconductor devices and, more particularly, to a system and method for delivering power to a semiconductor device.

### BACKGROUND OF THE INVENTION

The size of integrated circuit packages have grown in recent years. Increasing the size of package substrates results in levels of substrate warping which are unacceptable. Warping causes problems with the installation and retainment of the package on the motherboard. Such problems can lead to failure and disposal of the motherboards, which can be very expensive. In addition, delivery of power and ground to the substrate through the motherboard has become problematic due to the large number of power and ground connections required by the package substrate.

### SUMMARY OF THE INVENTION

The present invention provides a system and method for delivering power to a semiconductor device that substantially eliminates or reduces at least some of the disadvantages and problems associated with previous systems and methods.

In accordance with a particular embodiment of the present invention, a system for delivering power to a semiconductor device includes a package substrate comprising a substrate top surface and a substrate bottom surface. The system includes a connector formed on the substrate top surface and a cable coupled to the connector. The cable is operable to deliver power and ground to a top of the package substrate.

The cable may be further operable to deliver input/output (I/O) to the top of the package substrate. The cable may comprise a single metal layer or multi-metal-layer polyimide cable or a ribbon cable. The cable may be formed on the substrate top surface using a solder reflow process. The system may also include at least one additional connector formed on the substrate top surface and at least one additional cable coupled to the at least one additional connector. The at least one additional cable may be operable to deliver power to the top of the package substrate.

In accordance with another embodiment, a method for delivering power to a semiconductor device includes forming a connector on a substrate top surface of a package substrate and coupling the package substrate to a printed circuit board. The method includes coupling a cable to the connector and delivering power and ground to a top of the package substrate through the cable. Forming a connector on the substrate top surface may comprise forming a connector on the substrate top surface using a solder reflow process in the semiconductor device manufacturing process.

In accordance with yet another embodiment, a printed circuit board comprises a plurality of package substrates formed upon the printed circuit board. Each package substrate comprises a substrate top surface. The printed circuit board includes a plurality of connectors formed directly upon each substrate top surface and a cable coupled to each connector. Each cable is operable to deliver power and ground to a top of at least one of the plurality of package substrates. The printed circuit board may further comprise a power regulation module coupled to at least one of the cables. The power regulation module may be operable to regulate the power delivered to the top of at least one of the plurality of package substrates.

Technical advantages of particular embodiments of the present invention include a connector merged with a package substrate so that a cable coupled with the connector may be used to deliver power, ground and I/O to the top of the package substrate. Thus, a manufacturer may be able to reduce the number of power and ground layers formed in the printed circuit board. Accordingly, the cost and labor of manufacturing the printed circuit board may be reduced. Moreover, the conducting metal in the cable may be thicker than the metal in the power and ground layers of the printed circuit board, thus increasing the efficiency of the conducting metal used to deliver power and ground to the package substrate. Moreover, use of power and ground connections on the top surface of the substrate results in a concomitant reduction in required number of terminals on the bottom of the substrate, allowing a reduction in the substrate size.

Other technical advantages will be readily apparent to one skilled in the art from the following figures, descriptions and claims. Moreover, while specific advantages have been enumerated above, various embodiments may include all, some or none of the enumerated advantages.

### BRIEF DESCRIPTION OF THE DRAWINGS

For a more complete understanding of particular embodiments of the invention and their advantages, reference is now made to the following descriptions, taken in conjunction with the accompanying drawings, in which:

FIG. 1 illustrates a cross-sectional view of a partially completed semiconductor device with a connector, in accordance with an embodiment of the present invention;

FIG. 2 illustrates a cross-sectional view of a partially completed semiconductor device with two connectors, in accordance of a particular embodiment of the present invention;

FIG. 3 is a top view of a printed circuit board with package substrates and a power regulation module formed on the printed circuit board, in accordance of a particular embodiment of the present invention;

FIG. 4 is a top view illustrating a printed circuit board with package substrates formed on the printed circuit board, in accordance with another embodiment of the present invention; and

FIG. 5 is a flowchart illustrating a method for delivering power to a semiconductor device, in accordance with a particular embodiment of the present invention.

### DETAILED DESCRIPTION OF THE INVENTION

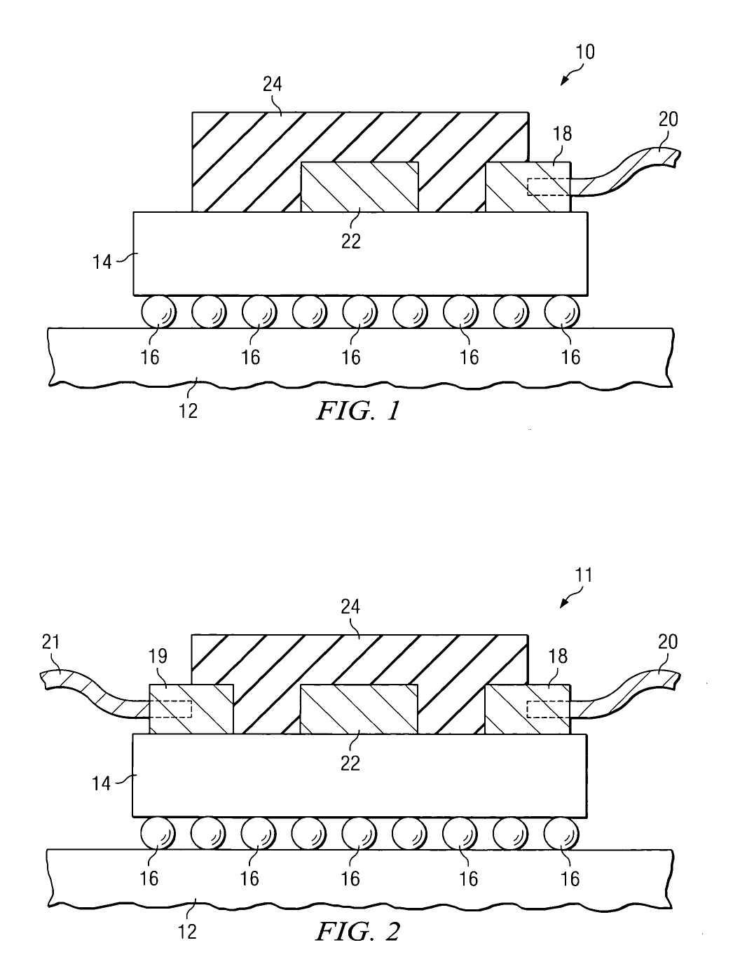

FIG. 1 illustrates a cross-sectional view of a partially completed semiconductor device 10, in accordance with an embodiment of the present invention. Semiconductor device 10 includes a printed circuit board 12. A package substrate 14 is coupled to printed circuit board 12 by a plurality of solder balls 16 to provide electrical connectivity between circuitry associated with printed circuit board 12 and circuitry associated with package substrate 14. For example, solder balls 16 may contact metal or other conductive material at both printed circuit board 12 and package substrate 14 such that solder balls 16 may provide electrical conductivity between circuitry associated with printed circuit board 12 and package substrate 14. In particular embodiments, solder balls 16 may be used for power, ground and input/output (I/O) connections. Additionally, although a specific number of solder balls 16 are illustrated, semiconductor device 10 may include any suitable number of solder balls 16 according to particular needs. Semiconductor device 10 also includes semiconductor chip 22 and lid 24 formed upon package substrate 14.

A surface mount connector 18, such as a low inductance connector, is formed onto package substrate 14. In particular embodiments connector 18 may be merged with package substrate 14 using a solder reflow process. Using a solder reflow process to merge connector 18 directly with package substrate 14 enables the connector to be formed on package substrate 14 during the normal manufacturing process of package substrate 14. For example, package substrate 14 may be put through a furnace in order to include components such as chip capacitors with a substrate, and such furnace process may be utilized to merge connector 18 with package substrate 14.

The formation of connector 18 upon package substrate 14 enables power, ground and I/O to be brought directly into package substrate 14 through a cable 20. In particular embodiments, cable 20 may comprise a flex cable, such as a low inductance ribbon cable, or a single or multi-layer polyimide cable. Other embodiments may include other types of cables for bringing power, ground and/or I/O to package substrate 14 through connector 18. In some embodiments, cable 20 may include bypass capacitors so that power regulation and filtering may be performed through the cable. Capacitors may be distributed along the top of the cable to enable decoupling of noise from power and ground planes of the cable.

In particular embodiments, the power and ground brought directly to package substrate 14 through cable 20 may comprise core power and ground. Such core power and ground supplies the circuitry for the die. In some embodiments, core power and ground may comprise approximately 15% to 40% of the total power and ground current of the package.

The ability to supply power, ground and I/O to the top of package substrate 14 through cable 20 may enable a manufacturer to reduce the number of power and ground layers formed in the printed circuit board. Thus, the cost and labor of manufacturing the printed circuit board may be reduced. Moreover, the conducting metal in the cable may be thicker than the metal in the power and ground layers of the printed circuit board, thus increasing the efficiency of the conducting metal. For example, metal in the printed circuit board may have a thickness of approximately 12 microns, while metal in a polyimide cable may have a thickness of approximately 25 microns. A ribbon cable may include metal having a thickness of approximately 500 microns.

FIG. 2 illustrates a cross-sectional view of a partially completed semiconductor device 11, in accordance with another embodiment of the present invention. Like semiconductor device 10 of FIG. 1, semiconductor device 11 includes a package substrate 14 coupled to printed circuit board 12 by a plurality of solder balls 16. Semiconductor device 11 includes semiconductor chip 22 and lid 24 formed upon package substrate 14. Semiconductor device 11 also includes connector 18 formed onto package substrate 14. Cable 20 delivers power, ground and I/O directly into package substrate 14. Semiconductor device 11 additionally includes connector 19 formed onto package substrate 14. Cable 21 couples to connector 19 to deliver power, ground and I/O directly into substrate 14. Thus, as illustrated, some embodiments may include more than one cable for supplying power and ground to a package substrate through surface mount connectors merged directly with the substrate.

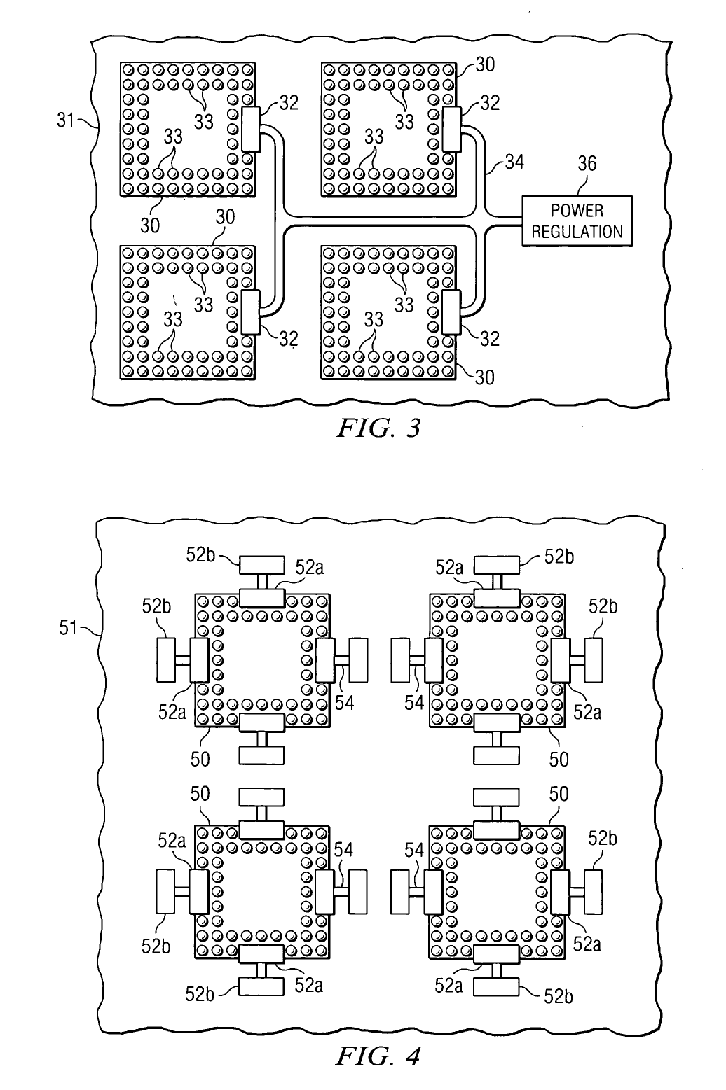

FIG. 3 is a top view of a printed circuit board 31 with package substrates 30 and a power regulation module 36 formed on the printed circuit board, in accordance of a particular embodiment of the present invention. Package substrates 30 include connectors 32 formed on the package substrates for bringing core power and ground to the top of package substrates 30. The core power and ground is brought to the top of package substrates 30 through a cable 34 coupled to connectors 32. A power regulation module 36 regulates the core power brought to the top of package substrates 30. FIG. 3 also includes balls 33 which serve only to illustrate the interconnection between package substrates 30 and printed circuit board 31 on the bottom surface of the package substrates.

FIG. 4 is a top view illustrating a printed circuit board 51 with package substrates 50 formed on the printed circuit board, in accordance with another embodiment of the present invention. Package substrates 50 include connectors 52A and 52B for bringing core power and ground to the top of package substrates 50. Connectors 52A are coupled directly to package substrates 50, while connectors 52B are coupled directly to printed circuit board 51. Power is brought from connectors 52B to connectors 52A through cables 54 coupled between connectors 52A and 52B. It should be understood that particular embodiments may utilize any combination of shorter cables 54 of FIG. 4 and longer cables 34 of FIG. 3 according to particular needs. As discussed above with respect to FIG. 3, FIG. 4 also includes balls which serve only to illustrate the interconnection between package substrates 50 and printed circuit board 51 on the bottom surface of the package substrates.

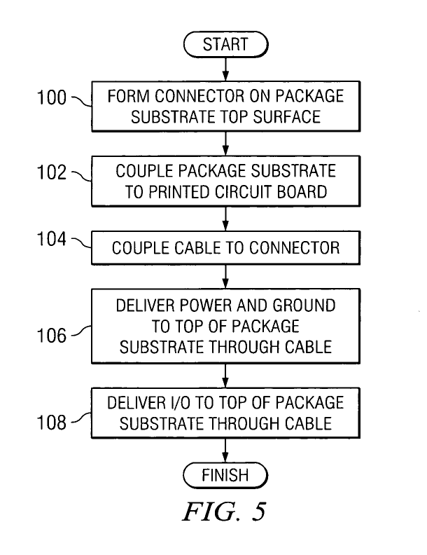

FIG. 5 is a flowchart illustrating a method for delivering power to a semiconductor device, in accordance with a particular embodiment of the present invention. The method begins at step 100 where a connector is formed on a package substrate. The package substrate comprises a substrate top surface and a substrate bottom surface. The connector may be merged directly with the substrate top surface during the normal package manufacturing process. For example, the connector may be formed upon the substrate top surface using a solder reflow process. At step 102, the package substrate is coupled to a printed circuit board. The package substrate may be formed upon solder balls coupled to the printed circuit board.

At step 104, a cable is coupled to the connector. The cable may comprise a single or multi-layer polyimide cable. In some embodiments, the cable may comprise a flex cable or a ribbon cable. At step 106, power and ground is delivered to the top of the package substrate through the cable. At step 108, I/O is delivered to the top of the package substrate through the cable.

Some of the steps illustrated in FIG. 5 may be combined, modified or deleted where appropriate, and additional steps may also be added to the flowchart. Additionally, steps may be performed in any suitable order without departing from the scope of the invention.

Although the present invention has been described in detail with reference to particular embodiments, it should be understood that various other changes, substitutions, and alterations may be made hereto without departing from the spirit and scope of the present invention. For example, although the present invention has been described with reference to a number of elements formed upon a printed circuit board and a package substrate, it should be understood that printed circuit boards and package substrates in accordance with particular embodiments may include other elements in order to accommodate particular needs. The present invention contemplates great flexibility in the arrangement of these elements as well as their internal components.

Numerous other changes, substitutions, variations, alterations and modifications may be ascertained by those skilled in the art and it is intended that the present invention encompass all such changes, substitutions, variations, alterations and modifications as falling within the spirit and scope of the appended claims. Moreover, the present invention is not intended to be limited in any way by any statement in the specification that is not otherwise reflected in the claims.

1. A system for delivering power to a semiconductor device, comprising:
a package substrate comprising a substrate top surface and a substrate bottom surface;
a connector formed on the substrate top surface; and
a cable coupled to the connector, the cable operable to deliver power and ground to a top of the package substrate.

2. The system of claim 1, wherein the cable is further operable to deliver input/output (I/O) to the top of the package substrate.

3. The system of claim 1, wherein the cable comprises a single metal layer polyimide cable.

4. The system of claim 1, wherein the cable comprises a multi-metal-layer polyimide cable.

5. The system of claim 4, wherein the cable comprises bypass capacitors for power regulation.

6. The system of claim 4, wherein the polyimide cable comprises metal having a thickness of approximately twenty-five microns.

7. The system of claim 1, wherein the cable comprises a ribbon cable.

8. The system of claim 7, wherein the ribbon cable comprises metal having a thickness of approximately five hundred microns.

9. The system of claim 1, wherein the cable is formed on the substrate top surface using a solder reflow process.

10. The system of claim 1, further comprising:
at least one additional connector formed on the substrate top surface; and
at least one additional cable coupled to the at least one additional connector, the at least one additional cable operable to deliver at least one of power and ground to the top of the package substrate.

11. A method for delivering power to a semiconductor device, comprising:
forming a connector on a substrate top surface of a package substrate;
coupling the package substrate to a printed circuit board;
coupling a cable to the connector; and
delivering power and ground to a top of the package substrate through the cable.

12. The method of claim 11, further comprising delivering input/output (I/O) to the top of the package substrate through the cable.

13. The method of claim 11, wherein the cable comprises a single metal layer polyimide cable.

14. The method of claim 11, wherein the cable comprises a multi-metal-layer polyimide cable.

15. The method of claim 14, wherein the cable comprises bypass capacitors for power regulation.

16. The method of claim 11, wherein the cable comprises a flex cable.

17. The method of claim 11, wherein forming a connector on the substrate top surface comprises forming a connector on the substrate top surface using a solder reflow process.

18. The method of claim 11, further comprising:
forming at least one additional connector on the substrate top surface;
coupling at least one additional cable to the at least one additional connector; and
delivering at least one of power, ground and input/output (I/O) to a top of the package substrate through the at least one additional cable.

19. A printed circuit board, comprising:
a plurality of package substrates formed upon a printed circuit board, each package substrate comprising a substrate top surface;
a plurality of connectors formed directly upon each substrate top surface; and
a cable coupled to each connector, each cable operable to deliver power and ground to a top of at least one of the plurality of package substrates.

20. The printed circuit board of claim 19, further comprising a power regulation module coupled to at least one of the cables, the power regulation module operable to regulate the power delivered to the top of at least one of the plurality of package substrates.
